(19) United States
(12) Patent Application Publication
(10) Pub. No.: US 2026/0122979 A1
(43) Pub. Date: Apr. 30, 2026

(54) ARRAY SUBSTRATE, METHOD FOR MANUFACTURING ARRAY SUBSTRATE, DISPLAY PANEL, AND DISPLAY DEVICE

(71) Applicant: HKC CORPORATION LIMITED, Shenzhen (CN)

(72) Inventors: Yongfeng LI, Shenzhen (CN); Hejun NING, Shenzhen (CN); Ying SONG, Shenzhen (CN); Yangchuan ZHOU, Shenzhen (CN); Xueyong HUANG, Shenzhen (CN); Chunlei SHI, Shenzhen (CN); Lidan YE, Shenzhen (CN)

(21) Appl. No.: 19/366,638

(22) Filed: Oct. 23, 2025

(30) Foreign Application Priority Data
Oct. 31, 2024 (CN) 202411540937.8

(51) Int. Cl. H10D 62/00; H10D 30/01; H10D 30/67; H10D 86/40; H10D 86/60

(52) U.S. Cl. CPC H10D 62/021; H10D 30/0316; H10D 30/6732; H10D 30/6757; H10D 86/441; H10D 86/60

(57) ABSTRACT

An array substrate includes a substrate, a transistor, and an insulating layer. The transistor has a gate, an active layer, a source, a drain, and a protector. The insulating layer covers the gate and a face of the substrate. The active layer is disposed on a face of the insulating layer away from the substrate. Both the source and the drain are disposed on the face of the insulating layer away from the substrate, the source faces and is spaced apart from the drain in a first direction, and both the source and the drain are connected to the active layer. The protector is disposed on a face of the active layer away from the insulating layer, and the protector is spaced apart from both the source and the drain.

### CROSS-REFERENCE TO RELATED APPLICATION(S)

This application claims priority under 35 U.S.C. § 119(a) to Chinese Patent Application No. 202411540937.8, filed Oct. 31, 2024, the entire disclosure of which is incorporated herein by reference.

### TECHNICAL FIELD

The disclosure relates to the field of display technology, and in particular, to an array substrate, a method for manufacturing an array substrate, a display panel, and a display device.

### BACKGROUND

With the development of display technology, display devices have been widely applied in various fields and industries. The display device includes a display panel for displaying images. The display panel includes multiple sub-pixels, and each sub-pixel is provided with a transistor therein for controlling a potential magnitude.

The transistor generally includes a gate, a source, a drain, and an active layer. During the manufacture of the transistor, when the source and drain are patterned through a mask, a chemical solution used may cause certain corrosion damage to the active layer, resulting in a negative shift in dielectric relaxation (DR) characteristics of the transistor, which eventually leads to vertical display Mura on the display panel.

Therefore, how to address the issue in the related art in which corrosion damage to the active layer caused by the chemical solution results in a negative shift in the DR characteristics of the transistor is a problem urgently to be solved by those of skill in the art.

### SUMMARY

In a first aspect of embodiments of the disclosure, an array substrate is provided. The array substrate includes a substrate, a transistor, and an insulating layer. The transistor and the insulating layer are disposed on the substrate. The transistor has a gate, an active layer, a source, a drain, and at least one protector. The insulating layer covers the gate and a face of the substrate. The active layer is disposed on a face of the insulating layer away from the substrate, and an orthographic projection of the active layer on the substrate at least partially overlaps an orthographic projection of the gate on the substrate. Both the source and the drain are disposed on the face of the insulating layer away from the substrate, the source faces and is spaced apart from the drain in a first direction, and both the source and the drain are connected to the active layer. The at least one protector is disposed on a face of the active layer away from the insulating layer, and the at least one protector is spaced apart from both the source and the drain. The at least one protector is configured to reduce a flow rate of a chemical solution for a patterning of the source and the drain.

In a second aspect of the embodiments of the disclosure, a method for manufacturing the array substrate is further provided. The method for manufacturing the array substrate includes the following. A substrate is provided. A gate, an insulating layer, and an active layer are formed sequentially on the substrate, where the insulating layer covers the gate and the substrate, and the active layer is disposed on a face of the insulating layer away from the gate. A conductive layer is formed on a face of the insulating layer away from the substrate, where the conductive layer covers the active layer. A first mask and a second mask are formed on a face of the conductive layer away from the insulating layer, and at least one third mask is formed on a face of the conductive layer away from the active layer, where the at least one third mask is positioned between the first mask and the second mask, and any two among the first mask, the second mask, and the at least one third mask are spaced apart from each other. Portions of the conductive layer offset from the first mask, the second mask, and the at least one third mask are removed to form a source, a drain, and at least one protector, where the at least one protector is positioned between the source and the drain, any two among the source, the drain, and the at least one protector are spaced apart from each other, both the source and the drain are connected to the active layer, and the at least one protector is positioned on a face of the active layer away from the insulating layer. The first mask, the second mask, and the at least one third mask are removed.

In a third aspect of the embodiments of the disclosure, a display panel is further provided. The display panel includes a driver chip and the array substrate, where the driver chip is electrically connected to the array substrate and is configured to provide a display signal to the array substrate.

In a fourth aspect of the embodiments of the disclosure, a display device is further provided. The display device includes a power board and the display panel, where the power board is electrically connected to the display panel and is configured to power the display panel.

### BRIEF DESCRIPTION OF THE DRAWINGS

To describe technical solutions in embodiments of the disclosure more clearly, the following briefly introduces the accompanying drawings required for describing the embodiments. Apparently, the accompanying drawings in the following description only illustrate some embodiments of the disclosure. Those of ordinary skill in the art may also obtain other drawings based on these accompanying drawings without creative efforts.

FIG. 1 is a schematic structural diagram of a layer structure of a display device disclosed in an embodiment of the disclosure.

FIG. 2 is a schematic structural diagram of a layer structure of a display panel disclosed in another embodiment of the disclosure.

FIG. 3 is a schematic structural diagram of a first type of layer structure of the array substrate disclosed in another embodiment of the disclosure.

FIG. 4 is a schematic structural diagram of a second type of layer structure of the array substrate disclosed in another embodiment of the disclosure.

FIG. 5 is a schematic flow chart of a method for manufacturing an array substrate disclosed in another embodiment of the disclosure.

FIG. 6 is a schematic structural diagram of a structure formed at S10 illustrated in FIG. 5.

FIG. 7 is a schematic structural diagram of a structure formed at S20 illustrated in FIG. 5.

FIG. 8 is a schematic structural diagram of a structure formed at S30 illustrated in FIG. 5.

FIG. 9 is a schematic structural diagram of a structure formed at S40 illustrated in FIG. 5.

FIG. 10 is a schematic structural diagram of an active layer formed by an existing process.

FIG. 11 is a schematic structural diagram of an active layer formed by a method for manufacturing an array substrate disclosed in the disclosure.

FIG. 12 is a schematic diagram illustrating a comparison between a DR characteristic curve of a transistor of the disclosure and a DR characteristic curve of a transistor in the related art.

Reference numerals are described as follows:

1—display device; 10—display panel; 11—array substrate; 12—liquid crystal layer; 13—color filter substrate; 30—backlight module; 111—substrate; 112—transistor; 113—insulating layer; 110—conductive layer; 120—first mask; 130—second mask; 140—third mask; 1121—gate; 1122—active layer; 1123—source; 1124—drain; 1125—protector; Operations at S10 to S50—steps of the method for manufacturing the array substrate.

### DETAILED DESCRIPTION

For ease understanding of the disclosure, the disclosure is described more completely with reference to the accompanying drawings hereinafter. The accompanying drawings illustrate preferred embodiments of the disclosure. However, the disclosure can be implemented in various forms and is not limited to the embodiments described herein. Rather, these embodiments are provided for a more thorough and comprehensive understanding of the disclosure.

The following embodiments are described with reference to the accompanying drawings to exemplify particular embodiments that may be implemented by the disclosure. The serial numbers themselves, such as “first” and “second” are used herein to distinguish the objects described, and do not have any sequential or technical meaning. The terms “connect” and “couple” in the disclosure include direct and indirect connections (couplings), unless otherwise specified. Directional terms such as “up”, “down”, “front”, “back”, “left”, “right”, “inside”, “outside”, “side”, and the like referred to herein which are only for directions with reference to the accompanying drawings. Therefore, the directional terms used herein are intended to better and more clearly illustrate and understand the disclosure, rather than explicitly or implicitly indicate that apparatus or components referred to herein must have a certain direction or be configured or operated in a certain direction and therefore cannot be understood as limitation on the disclosure.

It is noted that, in the description of the disclosure, terms “install”, “connect”, and “interconnect” may be understood in a broad sense unless otherwise expressly specified and limited. For example, the terms “install”, “connect”, and “interconnect” may refer to fixedly connect, detachably connect, or integrally connect, may refer to mechanically connect, and may refer to a directly connect, indirectly connect through an intermediate medium, or an intercommunicate interiors of two elements. For those of ordinary skill in the art, the specific meanings of the above terms in the disclosure can be understood according to specific situations. It is noted that, the terms such as “first” and “second” in the specification, claims, and the accompanying drawings of the disclosure are used for distinguishing between different objects rather than describing a particular order. In addition, terms such as “include”, “may include”, “contain”, or “may contain” used herein indicate the existence of the corresponding function, operation, element, etc. disclosed, and do not limit the other one or more further functions, operations, elements, etc. In addition, the term “include” or “contain” indicates the existence of the corresponding feature, number, step, operation, element, component, or combination thereof disclosed in the specification, without excluding the existence or addition of one or more other features, numbers, steps, operations, elements, components, or combinations thereof, and is intended to cover non-exclusive inclusion. It is also understood that the term “at least one” as described herein means one or more, such as one, two, or three, and the term “a plurality of” or “multiple” means at least two, such as two or three, unless otherwise expressly and specifically defined.

Unless otherwise defined, all technical and scientific terms used herein have the same meaning as commonly understood by those of ordinary skill in the art of the disclosure. The terms used herein in the disclosure are for merely describing embodiments rather than intending to limit the disclosure.

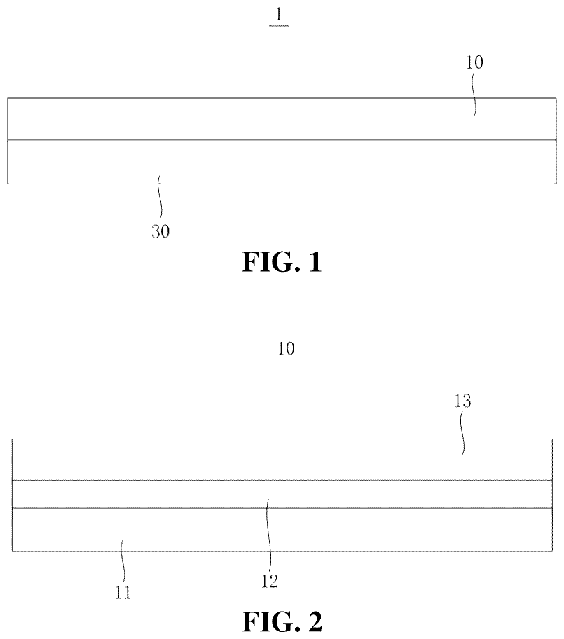

Referring to FIG. 1, which is a schematic structural diagram of a layer structure of a display device disclosed in an embodiment of the disclosure. The display device 1 may be used in, but is not limited to, electronic devices such as televisions, tablet computers, notebook computers, desktop computers, mobile phones, and in-vehicle displays. According to the embodiments of the disclosure, the specific type of the display device 1 is not particularly limited, and those of ordinary skill in the art may design accordingly based on the specific usage requirements of the display device 1, which will not be elaborated herein.

The display device 1 includes a display panel 10 and a backlight module 30 that is stacked with the display panel 10. The display panel 10 is disposed on a light-emitting side of the backlight module 30. The backlight module 30 is configured to provide backlight. The display panel 10 is configured to display images under the backlight provided by the backlight module 30.

In the embodiments of the disclosure, the backlight module 30 illustrated in FIG. 1 may be an edge-lit backlight module or a direct-lit backlight module. The display panel 10 may be a twisted nematic (TN) panel, a vertical alignment (VA) panel, an in-plane switching (IPS) panel, or a fringe field switching (FFS) panel, which will not be elaborated herein.

In exemplary embodiments, the display device 1 may further include a driving board, a power board, a high-voltage board, and a key control board, as well as other necessary components and elements. Those of ordinary skill in the art may supplement these parts accordingly based on the specific type and practical functions of the display device 1, which will not be elaborated herein. The power board is electrically connected to the display panel and configured to power the display panel.

In some embodiments, the display device 1 may further include a processor and a memory. The processor is electrically connected to the display panel 10 and configured to control displaying of the display panel 10. The memory is electrically connected to the processor and configured to store program code required for operation of the processor and for controlling the display content of the display panel 10.

In exemplary embodiments, the memory may include volatile memory, such as random access memory (RAM); the memory may also include non-volatile memory (NVM), such as read-only memory (ROM), flash memory (FM), a hard disk drive (HDD), or a solid-state drive (SSD). The memory may further include a combination of the above types of memory.

In exemplary embodiments, the processor includes one or more general-purpose processors, where the general-purpose processor may be any type of device capable of processing electronic instructions, including but not limited to a central processing unit (CPU), a microprocessor, a microcontroller, a main processor, or a controller. The processor is configured to execute various types of digital storage instructions, such as software or firmware programs stored in the memory, enabling the computing device to provide a broad range of services.

Referring to FIG. 2, which is a schematic structural diagram of a layer structure of a display panel disclosed in another embodiment of the disclosure. The display panel 10 includes an array substrate 11, a liquid crystal layer 12, and a color filter substrate 13. The array substrate 11 is disposed opposite to and spaced from the color filter substrate 13, and the liquid crystal layer 12 is disposed between the array substrate 11 and the color filter substrate 13. The array substrate 11 and the color filter substrate 13 are configured to form a predetermined electric field, which is used to drive the deflection of liquid crystal molecules in the liquid crystal layer 12, thereby changing a transmittance of the liquid crystal layer 12.

It may be noted that the array substrate 11 of the disclosure may also be applied to organic light-emitting diode (OLED) display panels, mini light-emitting diode (Mini LED) display panels, and micro light-emitting diode (Micro LED) display panels, which will not be limited herein. The display panel 10 may further include a driver chip electrically connected to the array substrate, and the driver chip is configured to provide an electrical signal for displaying of the array substrate.

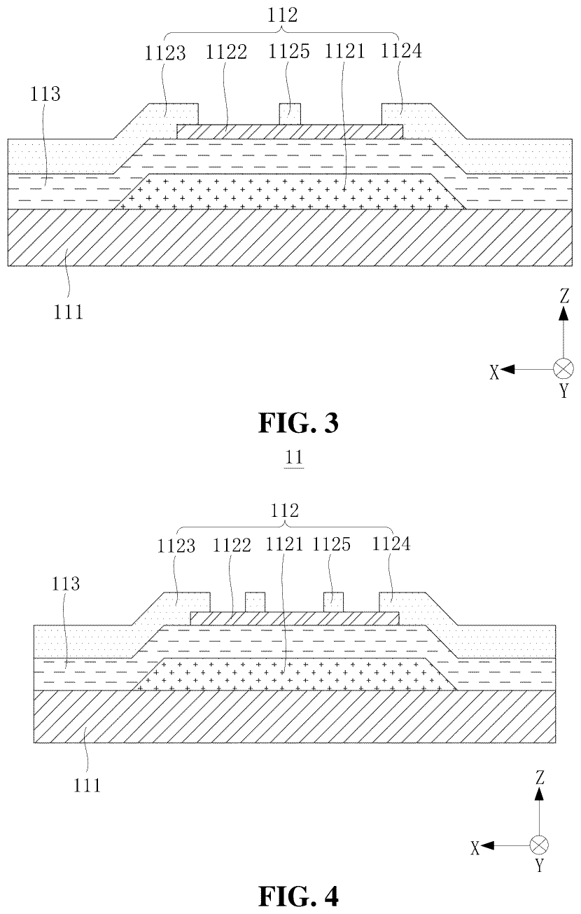

Referring to FIG. 3, which is a schematic structural diagram of a first type of layer structure of an array substrate disclosed in another embodiment of the disclosure. For ease of description, a longitudinal direction of the array substrate 11 illustrated in FIG. 3 is defined as X-axis direction, a lateral direction of the array substrate 11 illustrated in FIG. 3 is defined as Y-axis direction, and a thickness direction of the array substrate 11 illustrated in FIG. 3 is defined as Z-axis direction, where the X-axis direction, the Y-axis direction, and the Z-axis direction are mutually perpendicular in pairs. The X-axis direction may be defined as a first direction, and the Y-axis direction may be defined as a second direction.

The orientation terms such as “upper,” “lower,” “top,” and “bottom” mentioned in the embodiments of the disclosure are described with reference to orientations illustrated in FIG. 3 of the specification, where positive Z-axis direction is defined as “upper” or “top,” and negative Z-axis direction is defined as “lower” or “bottom”, which does not impose limitations on the practical applications of the array substrate 11.

In view of the above deficiencies in the related art, an object of the disclosure is to provide an array substrate, a method for manufacturing the array substrate, a display panel, and a display device, aiming to address the issue in the related art in which corrosion damage to the active layer caused by the chemical solution during the manufacture of the transistor results in a negative shift in the DR characteristics of the transistor.

Specifically, the array substrate 11 includes a substrate 111, multiple transistors 112, and an insulating layer 113. Each transistor 112 includes a gate 1121, an active layer 1122, a source 1123, a drain 1124, and a protector 1125. Both the gate 1121 and the insulating layer 113 are disposed on a face of the substrate 111. The insulating layer 113 covers a peripheral side face of the gate 1121 and a side face of the gate 1121 away from the substrate 111. That is, the insulating layer 113 covers the gate 1121 and the substrate 111. The active layer 1122 is disposed on a face of the insulating layer 113 away from the substrate 111. An orthographic projection of the active layer 1122 in the Z-axis direction on the substrate 111 at least partially overlaps an orthographic projection of the gate 1121 in the Z-axis direction on the substrate 111. That is, the orthographic projection of the active layer 1122 on the substrate 111 at least partially overlaps the orthographic projection of the gate 1121 on the substrate 111. Both the source 1123 and the drain 1124 are disposed on the face of the insulating layer 113 away from the substrate 111. The source 1123 is opposite to and spaced apart from the drain 1124 in the X-axis direction. The source 1123 and the drain 1124 are connected to two opposite sides of the active layer 1122, respectively. An orthographic projection of a portion of the source 1123 in the Z-axis direction on the substrate 111 partially overlaps an orthographic projection of the gate 1121 in the Z-axis direction on the substrate 111. An orthographic projection of a portion of the drain 1124 in the Z-axis direction on the substrate 111 partially overlaps an orthographic projection of the gate 1121 in the Z-axis direction on the substrate 111. In other words, the orthographic projection of a portion of the source 1123 on the substrate 111 partially overlaps the orthographic projection of the gate 1121 on the substrate 111, and the orthographic projection of a portion of the drain 1124 on the substrate 111 partially overlaps the orthographic projection of the gate 1121 on the substrate 111. The protector 1125 is disposed on a face of the active layer 1122 away from the insulating layer 113. The protector 1125 is positioned between one end of the source 1123 and one end of the drain 1124 that directly faces the one end of the source 1123. The protector 1125 is spaced apart from both the source 1123 and the drain 1124.

The insulating layer 113 electrically insulates the gate 1121 from the active layer 1122, the source 1123, and the drain 1124. The source 1123 is electrically connected to the active layer 1122, and the drain 1124 is electrically connected to the active layer 1122. The gate 1121 is configured to form a control electric field, which is used to activate the active layer 1122, thereby electrically conducting a path between the source 1123 and the drain 1124. The protector 1125 is configured to reduce the flow rate of the chemical solution for the patterning of the source 1123 and the drain 1124, thereby reducing the corrosion damage to the active layer 1122 cause by the chemical solution, and preventing vertical display Mura on the display panel 10 caused by a negative shift in the DR characteristics of the transistor 112. In the disclosure, patterning refers to the process of etching the conductive layer to form the source 1123 and the drain 1124.

In exemplary embodiments, the protector 1125 is implemented as one protector 1125.

In exemplary embodiments, the source 1123, the drain 1124, and the protector 1125 are made of a same material. All the source 1123, the drain 1124, and the protector 1125 are formed in a single etching process.

Referring to FIG. 4, which is a schematic structural diagram of a second type of layer structure of the array substrate disclosed in another embodiment of the disclosure. The difference between the array substrate 11 of the second type of layer structure and the array substrate 11 of the first type of layer structure lies in that: the number of protectors 1125 in the array substrate 11 of the second type of layer structure is two.

It may be noted that, for ease of illustration, the number of protectors 1125 in FIG. 3 is one, and the number of protectors 1125 in FIG. 4 is two. In practice, the number of protectors 1125 may be at least one, that is, the number of protectors 1125 may be one, two, or greater than two, which is not limited herein.

The multiple protectors 1125 are spaced apart from each other in the X-axis direction in sequence.

In exemplary embodiments, a dimension of the active layer 1122 in the X-axis direction ranges from 20 μm to 100 μm, for example, 20 μm, 30 μm, 37 μm, 45 μm, 50 μm, 61 μm, 76 μm, 80 μm, 90 μm, 100 μm, or other values, which is not limited herein.

In exemplary embodiments, a dimension of the active layer 1122 in the Y-axis direction ranges from 4 μm to 8 μm, for example, 4 μm, 5 μm, 5.5 μm, 5.8 μm, 6 μm, 6.3 μm, 7 μm, 7.6 μm, 8 μm, or other values, which is not limited herein. A dimension of the protector 1125 in the Y-axis direction is greater than the dimension of the active layer 1122 in the Y-axis direction.

It may be understood that by setting the dimension of the protector 1125 in the Y-axis direction to be greater than the dimension of the active layer 1122 in the Y-axis direction, the protector 1125 can more effectively reduce the flow rate of the chemical solution, and can also reduce a contact area between the active layer 1122 and the chemical solution, thereby reducing the corrosion damage to the active layer 1122 caused by the chemical solution.

In exemplary embodiments, a dimension of the protector 1125 in the X-axis direction ranges from 0.5 μm to 3 μm, for example, 0.5 μm, 0.8 μm, 1 μm, 1.4 μm, 1.9 μm, 2 μm, 2.5 μm, 3 μm, or other values, which is not limited herein.

It may be understood that if the dimension of the protector 1125 in the X-axis direction is less than 0.5 μm, the protector 1125 is prone to detachment from the active layer 1122, which will increase the contact area between the active layer 1122 and the chemical solution. If the dimension of the protector 1125 in the X-axis direction is greater than 3 μm, the protector 1125 is likely to couple with the source 1123, thereby affecting the potential of the source 1123, and the protector 1125 is also likely to couple with the drain 1124, thereby affecting the potential of the drain 1124. Therefore, by setting the dimension of the protector 1125 in the X-axis direction to range from 0.5 μm to 3 μm, detachment of the protector 1125 from the active layer 1122 can be avoided, the contact area between the active layer 1122 and the chemical solution can be reduced, and the impact of the protector 1125 on the potentials of the source 1123 and the drain 1124 can be avoided.

In exemplary embodiments, the interval between two adjacent protectors 1125 ranges from 3 μm to 8 μm, for example, 3 μm, 3.4 μm, 4 μm, 4.8 μm, 5 μm, 5.5 μm, 6 μm, 7 μm, 7.2 μm, 8 μm, or other values, which is not limited herein.

It may be understood that if the interval between two adjacent protectors 1125 is less than 3 μm, coupling is likely to occur between the adjacent protectors 1125, thereby affecting the resistance and potential of the active layer 1122. If the interval is greater than 8 μm, the contact area between the active layer 1122 and the chemical solution increases. Therefore, by setting the interval between two adjacent protectors 1125 to range from 3 μm to 8 μm, coupling between the two protectors 1125 can be avoided, and the contact area between the active layer 1122 and the chemical solution can be reduced.

In exemplary embodiments, an interval between the source 1123 and one protector 1125 that is positioned closest to the source 1123 ranges from 3 μm to 8 μm, for example, 3 μm, 3.4 μm, 4 μm, 4.8 μm, 5 μm, 5.5 μm, 6 μm, 7 μm, 7.2 μm, 8 μm, or other values, which is not limited herein.

It may be understood that by setting the interval between the source 1123 and the one protector 1125 that is positioned closest to the source 1123 to range from 3 μm to 8 μm, coupling between the source 1123 and the protector 1125 can be avoided, and the contact area between the active layer 1122 and the chemical solution can be reduced.

In exemplary embodiments, the interval between the drain 1124 and one protector 1125 that is positioned closest to the drain 1124 ranges from 3 μm to 8 μm, for example, 3 μm, 3.4 μm, 4 μm, 4.8 μm, 5 μm, 5.5 μm, 6 μm, 7 μm, 7.2 μm, 8 μm, or other values, which is not limited herein.

It may be understood that by setting the interval between the drain 1124 and the one protector 1125 that is positioned closest to the drain 1124 to range from 3 μm to 8 μm, coupling between the drain 1124 and the protector 1125 can be avoided, and the contact area between the active layer 1122 and the chemical solution can be reduced.

It may be noted that, for ease of illustration, only one transistor is illustrated in FIG. 3 and FIG. 4. The number of transistors in the array substrate 11 is determined by the number of subpixels, with one transistor being provided in each subpixel.

In exemplary embodiments, the array substrate 11 may further include a planarization layer and multiple pixel electrodes. The planarization layer covers the source 1123, the drain 1124, the active layer 1122, and the protector 1125. The multiple pixel electrodes are disposed on a face of the planarization layer away from the active layer 1122, and each pixel electrode is electrically connected to one drain 1124.

The color filter substrate 13 may further include a common electrode. The common electrode and the pixel electrodes together form the predetermined electric field.

In summary, the array substrate 11 provided in the embodiments of the disclosure includes the substrate 111, the transistor 112, and the insulating layer 113. The transistor 112 has the gate 1121, the active layer 1122, the source 1123, the drain 1124, and the protector 1125. The insulating layer 113 covers the gate 1121 and a face of the substrate 111. The active layer 1122 is disposed on a face of the insulating layer 113 away from the substrate 111. The orthographic projection of the active layer 1122 on the substrate 111 in the Z-axis direction overlaps the orthographic projection of the gate 1121 on the substrate 111 in the Z-axis direction. Both the source 1123 and the drain 1124 are disposed on the face of the insulating layer 113 away from the substrate 111. The source 1123 faces and is spaced apart from the drain 1124 in the X-axis direction, and both the source 1123 and the drain 1124 are connected to the active layer 1122. The protector 1125 is disposed on the face of the active layer 1122 away from the insulating layer 113. The protector 1125 is spaced apart from both the source 1123 and the drain 1124. The protector 1125 is configured to reduce the flow rate of the chemical solution for the patterning of the source 1123 and the drain 1124. As such, it can reduce the corrosion damage to the active layer 1122 caused by the chemical solution while ensuring sufficient etching of the source 1123 and the drain 1124, thereby preventing vertical display Mura on the display panel 10 caused by the negative shift in the DR characteristics of the transistor 112.

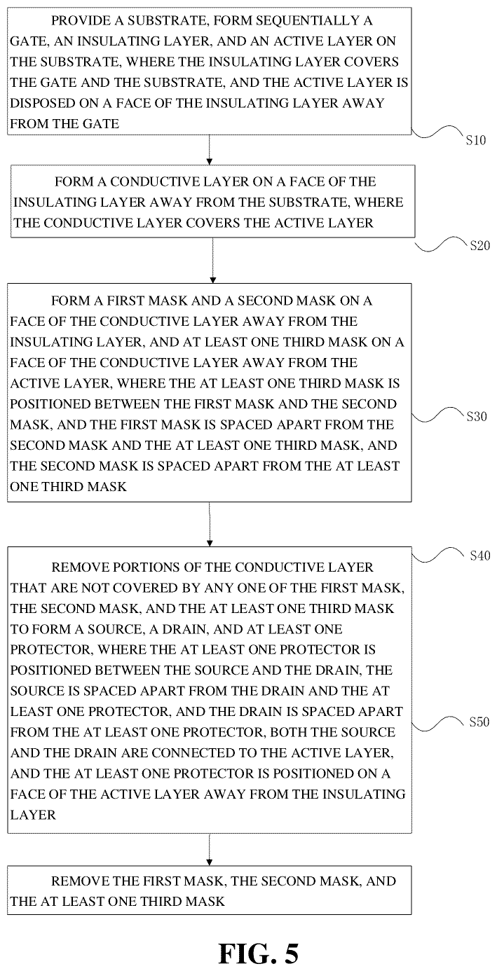

Referring to FIG. 5, which is a schematic flow chart of a method for manufacturing the array substrate disclosed in another embodiment of the disclosure. The method for manufacturing the array substrate is carried out to form the array substrate 11 in FIG. 3. For structure features involved in the method for manufacturing the array substrate that are identical to those of the array substrate 11, reference can be made to the relevant descriptions of the array substrate 11 in the embodiments above, which will not be repeated herein. As illustrated in FIG. 3, FIG. 4, and FIG. 5, the method for manufacturing the array substrate 11 specifically includes the following.

It may be noted that, for ease of illustration, the description and depiction of the method for manufacturing the array substrate 11 only show one transistor, whereas in practice multiple transistors can be formed simultaneously.

At S10, the substrate 111 is provided, and the gate 1121, the insulating layer 113, and the active layer 1122 are sequentially formed on the substrate 111, where the insulating layer 113 covers the gate 1121 and the substrate 111, and the active layer 1122 is disposed on the face of the insulating layer 113 away from the gate 1121.

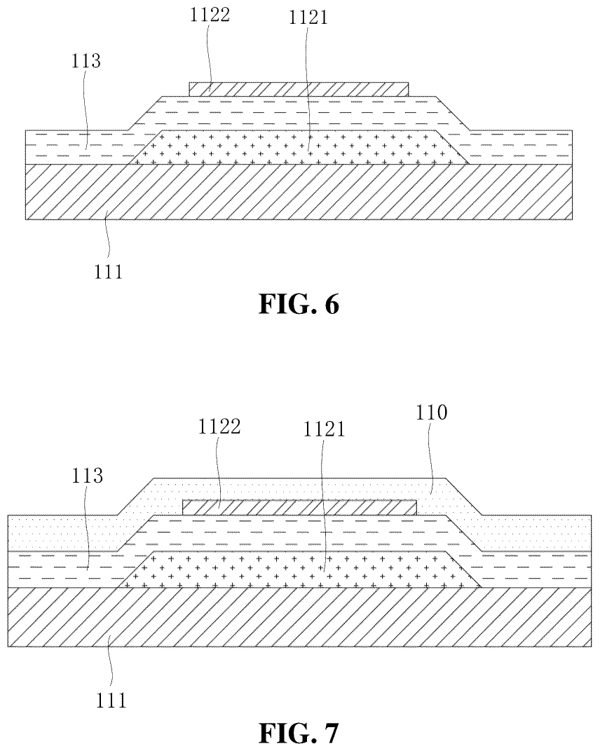

Specifically, referring to FIG. 6, which is a schematic structural diagram of a structure formed at S10 illustrated in FIG. 5. The orthographic projection of the gate 1121 on the substrate 111 at least partially overlaps the orthographic projection of the active layer 1122 on the substrate 111.

At S20, the conductive layer 110 is formed on the face of the insulating layer 113 away from the substrate 111, where the conductive layer 110 covers the active layer 1122.

Specifically, referring to FIG. 7, which is a schematic structural diagram of a structure formed at S20 illustrated in FIG. 5. The conductive layer 110 is formed on the face of the insulating layer 113 away from the substrate 111 through depositing. The conductive layer 110 covers a peripheral side face of the active layer 1122 and the face of the active layer 1122 away from the insulating layer 113. A material of the conductive layer 110 includes a metal.

At S30, the first mask 120 and the second mask 130 are formed on a face of the conductive layer 110 away from the insulating layer 113, and at least one third mask 140 is formed on a face of the conductive layer 110 away from the active layer 1122, where the at least one third mask 140 is positioned between the first mask 120 and the second mask 130, and the first mask 120, the second mask 130, and the third mask 140 are spaced apart from each other.

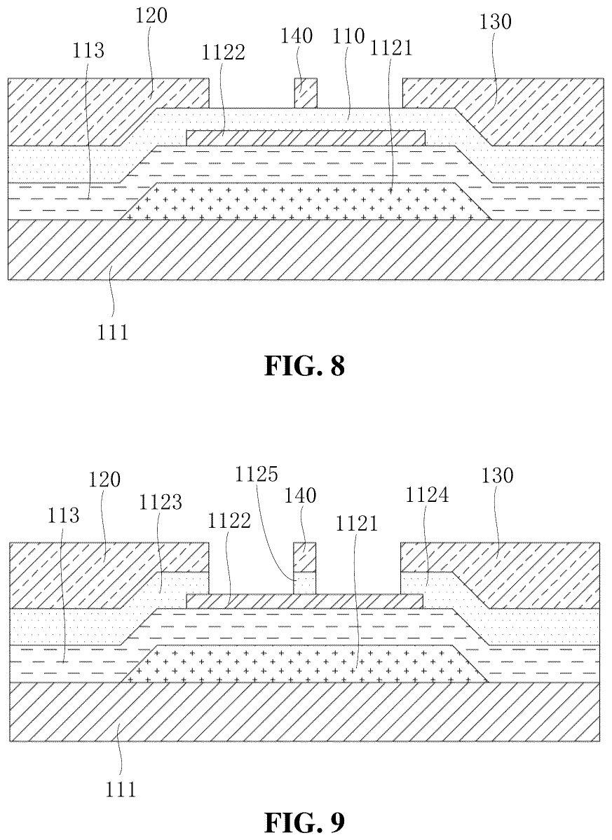

Specifically, referring to FIG. 8, which is a schematic structural diagram of a structure formed at S30 illustrated in FIG. 5. The first mask 120, the second mask 130, and at least one third mask 140 are formed through coating, exposure, development, etc., where the at least one third mask 140 is positioned between the first mask 120 and the second mask 130, and the first mask 120, the second mask 130, and the third mask 140 are spaced apart from each other. An orthographic projection of the first mask 120 on the substrate 111 partially overlaps the orthographic projection of the active layer 1122 on the substrate 111. An orthographic projection of the second mask 130 on the substrate 111 partially overlaps the orthographic projection of the active layer 1122 on the substrate 111. An orthographic projection of the third mask 140 on the substrate 111 falls within the orthographic projection of the active layer 1122 on the substrate 111. The first mask 120, the second mask 130, and the third mask 140 may all be photoresist.

It may be noted that, in FIG. 8, only one third mask 140 is illustrated, but the number of third masks 140 may also be two or more than two.

At S40, portions of the conductive layer 110 that are not covered by any one of the first mask 120, the second mask 130, and the at least one third mask 140 are removed to form the source 1123, the drain 1124, and the protector 1125, where the protector 1125 is positioned between the source 1123 and the drain 1124, and the source 1123, the drain 1124, and the protector 1125 are spaced apart from each other. Both the source 1123 and the drain 1124 are connected to the active layer 1122, and the protector 1125 is positioned on the face of the active layer 1122 away from the insulating layer 113.

Specifically, referring to FIG. 9, which is a schematic structural diagram of a structure formed at S40 illustrated in FIG. 5. The portions of the conductive layer 110 that are not covered by any one of the first mask 120, the second mask 130, and the at least one third mask 140 are removed through a wet process, to form the source 1123, the drain 1124, and the protector 1125, where the protector 1125 is positioned between the source 1123 and the drain 1124, and the source 1123, the drain 1124, and the protector 1125 are spaced apart from each other. Specifically, an orthographic projection of the source 1123 on the substrate 111 overlaps an orthographic projection of the first mask 120 on the substrate 111. An orthographic projection of the drain 1124 on the substrate 111 overlaps an orthographic projection of the second mask 130 on the substrate 111. An orthographic projection of the protector 1125 on the substrate 111 overlaps an orthographic projection of the third mask 140 on the substrate 111. Moreover, both the source 1123 and the drain 1124 are connected to the active layer 1122, and the protector 1125 is positioned on the face of the active layer 1122 away from the insulating layer 113.

The gate 1121, the active layer 1122, the source 1123, the drain 1124, and the protector 1125 together form the transistor 112.

At S50, the first mask 120, the second mask 130, and the third mask 140 are removed.

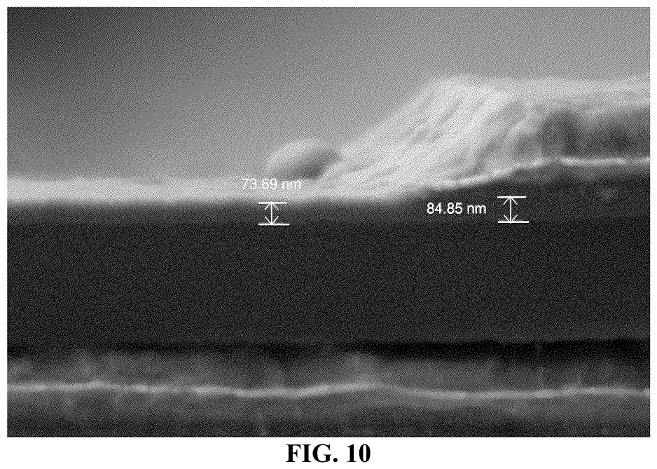

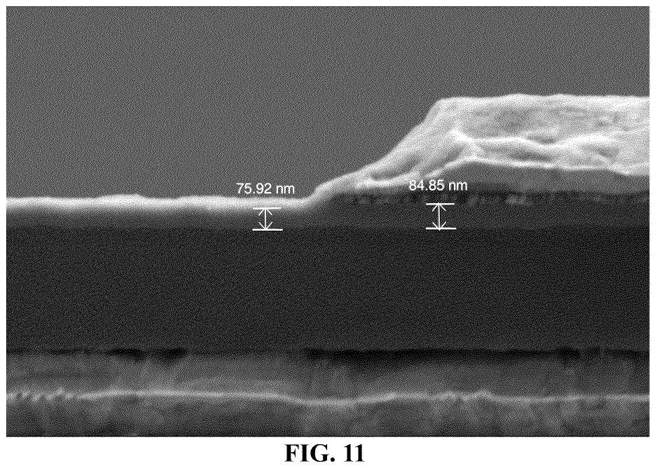

Referring to FIG. 10 and FIG. 11. FIG. 10 is a schematic structural diagram of an active layer formed by an existing process, and FIG. 11 is a schematic structural diagram of the active layer formed by the method for manufacturing the array substrate disclosed in the disclosure. A thickness of the active layer formed by the existing process is 73.69 nm, while a thickness of the active layer 1122 formed by the method for manufacturing the array substrate of the disclosure is 75.92 nm. That is, the thickness of the active layer formed by the method for manufacturing the array substrate of the disclosure is increased by 2.23 nm compared with the active layer formed by the existing process. Therefore, by forming the protector 1125 on the active layer 1122, the method for manufacturing the array substrate of the disclosure can reduce the flow rate of the chemical solution required for patterning the source 1123 and the drain 1124, and reduce the corrosion damage to the active layer 1122 caused by the chemical solution while ensuring sufficient etching of the source 1123 and the drain 1124.

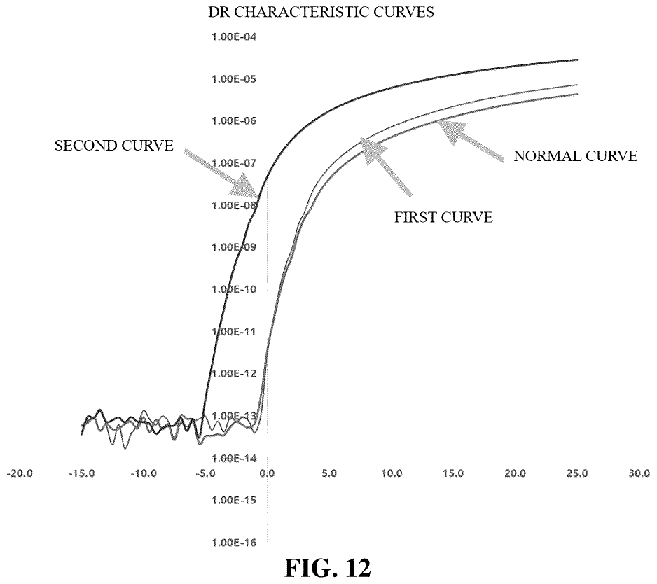

Referring to FIG. 12, which is a schematic diagram illustrating a comparison between a DR characteristic curve of the transistor of the disclosure and a DR characteristic curve of a transistor in the related art. In FIG. 12, a first curve represents the DR characteristic curve of the transistor of the disclosure, and a second curve represents the DR characteristic curve of the transistor in the related art. Referring to FIG. 10 and FIG. 11, since the thickness of the active layer of the transistor of the disclosure is greater than the thickness of the transistor in the related art, the DR characteristic curve of the transistor of the disclosure exhibits a forward shift of approximately 3 V relative to that of the transistor in the related art. Furthermore, the first curve is closer to a normal curve, where the normal curve represents a DR characteristic curve of a transistor with a standard active layer thickness. Therefore, the transistor 112 formed by the method for manufacturing the array substrate disclosed in the disclosure can prevent vertical display Mura on the display panel 10 caused by a negative shift in the DR characteristics of the transistor 112.

Moreover, the process for forming the protector 1125 in the disclosure does not result in an increase in the number of masks, nor does it introduce additional processing steps. Merely changing the position and number of masks does not lead to an increase in cost.

In the illustration of the disclosure, descriptions with reference to terms such as “one embodiment”, “some embodiments”, “exemplary embodiments”, “examples”, “specific examples”, and “some examples” mean that specific features, structures, materials, or characteristics described in combination with the embodiments or examples are included in at least one embodiment or example of the disclosure. The schematic expressions of the above terms herein do not necessarily refer to the same embodiment or example. Moreover, the particular features, structures, materials, or characteristics described may be combined in any suitable manner in any one or more embodiments or examples.

It may be understood that the disclosure is not to be limited to the above-identified embodiments. Those of ordinary skill in the art can make improvements or changes based on the above description, and all these improvements and changes should fall within the protection scope of the appended claims of the disclosure. Those of ordinary skill in the art can understand that all or part of methods for realizing the above embodiments, and equivalent changes made in accordance with the claims of the disclosure, still fall within the scope covered by the disclosure.

What is claimed is:

1. An array substrate, comprising a substrate, a transistor, and an insulating layer, the transistor and the insulating layer being disposed on the substrate, wherein
the transistor has a gate, an active layer, a source, a drain, and at least one protector;
the insulating layer covers the gate and a face of the substrate;
the active layer is disposed on a face of the insulating layer away from the substrate, and an orthographic projection of the active layer on the substrate at least partially overlaps an orthographic projection of the gate on the substrate;
both the source and the drain are disposed on the face of the insulating layer away from the substrate, the source faces and is spaced apart from the drain in a first direction, and both the source and the drain are connected to the active layer;
the at least one protector is disposed on a face of the active layer away from the insulating layer, and the at least one protector is spaced apart from both the source and the drain; and
the at least one protector is configured to reduce a flow rate of a chemical solution for a patterning of the source and the drain.

2. The array substrate according to claim 1, wherein a dimension of the active layer in a second direction ranges from 4 μm to 8 μm, a dimension of each of the at least one protector in the second direction is greater than the dimension of the active layer in the second direction, and the second direction is perpendicular to the first direction.

3. The array substrate according to claim 1, wherein a dimension of each of the at least one protector in the first direction ranges from 0.5 μm to 3 μm.

4. The array substrate according to claim 1, wherein the at least one protector is implemented as a plurality of protectors that are spaced apart from each other in the first direction, and a spacing between each two adjacent protectors of the plurality of protectors ranges from 3 μm to 8 μm.

5. The array substrate according to claim 1, wherein a spacing between the source and one of the at least one protector that is positioned closest to the source ranges from 3 μm to 8 μm.

6. The array substrate according to claim 1, wherein a spacing between the drain and one of the at least one protector that is positioned closest to the drain ranges from 3 μm to 8 μm.

7. The array substrate according to claim 1, wherein the source, the drain, and the at least one protector are made of a same material, and all the source, the drain, and the at least one protector are formed in a single etching process.

8. The array substrate according to claim 1, wherein an orthographic projection of the source on the substrate partially overlaps an orthographic projection of the gate on the substrate.

9. The array substrate according to claim 1, wherein an orthographic projection of the drain on the substrate partially overlaps an orthographic projection of the gate on the substrate.

10. The array substrate according to claim 1, wherein the at least one protector is positioned between one end of the source and one end of the drain that directly faces the one end of the source.

11. A method for manufacturing an array substrate, comprising:
providing a substrate;
forming sequentially a gate, an insulating layer, and an active layer on the substrate, wherein the insulating layer covers the gate and the substrate, and the active layer is disposed on a face of the insulating layer away from the gate;
forming a conductive layer on a face of the insulating layer away from the substrate, wherein the conductive layer covers the active layer;
forming a first mask and a second mask on a face of the conductive layer away from the insulating layer, and at least one third mask on a face of the conductive layer away from the active layer, wherein the at least one third mask is positioned between the first mask and the second mask, and the first mask is spaced apart from the second mask and the at least one third mask, and the second mask is spaced apart from the at least one third mask;
removing portions of the conductive layer that are not covered by any one of the first mask, the second mask, and the at least one third mask to form a source, a drain, and at least one protector, wherein the at least one protector is positioned between the source and the drain, the source is spaced apart from the drain and the at least one protector, and the drain is spaced apart from the at least one protector, both the source and the drain are connected to the active layer, and the at least one protector is positioned on a face of the active layer away from the insulating layer; and
removing the first mask, the second mask, and the at least one third mask.

12. A display device, comprising a power board and a display panel, wherein
the display panel comprises a driver chip and an array substrate, the driver chip is electrically connected to the array substrate and is configured to provide a display signal to the array substrate;
the power board is electrically connected to the display panel and is configured to power the display panel; and
the array substrate comprises a substrate, a transistor, and an insulating layer, the transistor and the insulating layer being disposed on the substrate, wherein
the transistor has a gate, an active layer, a source, a drain, and at least one protector;
the insulating layer covers the gate and a face of the substrate;
the active layer is disposed on a face of the insulating layer away from the substrate, and an orthographic projection of the active layer on the substrate at least partially overlaps an orthographic projection of the gate on the substrate;
both the source and the drain are disposed on the face of the insulating layer away from the substrate, the source faces and is spaced apart from the drain in a first direction, and both the source and the drain are connected to the active layer;
the at least one protector is disposed on a face of the active layer away from the insulating layer, and the at least one protector is spaced apart from both the source and the drain; and
the at least one protector is configured to reduce a flow rate of a chemical solution for a patterning of the source and the drain.

13. The display device according to claim 12, wherein a dimension of the active layer in a second direction ranges from 4 μm to 8 μm, a dimension of each of the at least one protector in the second direction is greater than the dimension of the active layer in the second direction, and the second direction is perpendicular to the first direction.

14. The display device according to claim 12, wherein a dimension of each of the at least one protector in the first direction ranges from 0.5 μm to 3 μm.

15. The display device according to claim 12, wherein the at least one protector is implemented as a plurality of protectors that are spaced apart from each other in the first direction, and a spacing between each two adjacent protectors of the plurality of protectors ranges from 3 μm to 8 μm.

16. The display device according to claim 12, wherein a spacing between the source and one of the at least one protector that is positioned closest to the source ranges from 3 μm to 8 μm.

17. The display device according to claim 12, wherein a spacing between the drain and one of the at least one protector that is positioned closest to the drain ranges from 3 μm to 8 μm.

18. The display device according to claim 12, wherein the source, the drain, and the at least one protector are made of a same material, and all the source, the drain, and the at least one protector are formed in a single etching process.

19. The display device according to claim 12, wherein an orthographic projection of the source on the substrate partially overlaps an orthographic projection of the gate on the substrate, and an orthographic projection of the drain on the substrate partially overlaps an orthographic projection of the gate on the substrate.

20. The display device according to claim 12, wherein insulating layer electrically insulates the gate from the active layer, the source, and the drain.
